(19) United States
(12) Patent Application Publication
(10) Pub. No.: US 2004/0224511 A1
(43) Pub. Date: Nov. 11, 2004

(54) Metal polishing

(76) Inventors: John E. Pillion, Brookline, NH (US); Jieh-Hwa Shyu, Andover, MA (US); Brett Belongia, North Andover, MA (US)

Correspondence Address: Timothy J King, Mykrolis Corporation, 129 Concord Road, Billerica, MA, 01821-4600, US

(21) Appl. No.: 10/487,484

(22) PCT Filed: Aug. 6, 2002
(86) PCT No.: PCT/US02/24851

Related U.S. Application Data
(60) Provisional application No. 60/314,409, filed on Aug. 23, 2001.

(51) Int. Cl. H01L 21/302

(52) U.S. Cl. 438/689

(57) ABSTRACT

The present invention provides a process and liquid composition for selectively removing a metal film from a patterned substrate. The process, which is useful in the manufacture of semiconductor devices and circuits, comprises chemically reacting the metal film with a liquid and then removing the reaction product from the metal surfaces using a polishing pad. The present invention further provides a process to polish a metal surface in separate stages and at different rates by changing the chemical composition of the liquid.

### FIELD OF INVENTION

This invention relates to a process and liquid composition for polishing inlaid patterns of metal on a substrate.

### BACKGROUND

The Damascene process is a back end of line semiconductor wafer manufacturing method used to create an inlaid pattern of metal interconnects within a patterned dielectric or barrier layer material. The Damascene process includes two process steps. In the first step, a blanket layer of metal, up to about 1.5 micrometers thick, is deposited on a substrate wafer using an electrolytic plating process. The blanket metal layer fills and covers the vias and trenched patterned in the substrate. In the second step, chemical mechanical polishing is used to remove excess metal from the substrate down to the surface of the patterned dielectric or barrier layer used to form the outline of the interconnect pattern. The polishing process yields an inlaid pattern of metal within the patterned dielectric or barrier material.

For advanced semiconductor devices utilizing the dual Damascene process, copper metal is used for the metal interconnects, silicon dioxide is used for the dielectric layer, and materials like tantalum or tantalum nitride are applied over the dielectric and are used for the barrier layers. Alternately, for advanced very large scale integrated circuits, organic, semi-organic or other low-k dielectric materials may be used as a dielectric in place of silicon dioxide.

Chemical mechanical planarization, CMP, is one process used to remove excess material from a surface. It typically includes the use of a polishing pad and a solution containing an abrasive along with passivating agents and/or chemical agents that either retard or assist the planing of the material. It is useful in the manufacture of semiconductors as the patterned substrates onto which the material is deposited are essentially flat. By planing the plated patterned surfaces down to top-most surface of the substrate, only the portion of the material desired to comprise the interconnects or insulator remains. The term “planarizing” is used in the semiconductor industry as a synonym for “planing.” Chemical mechanical planarization may be used for planing portions of wafers comprising dielectrics, such as silicon dioxide, or metals, such as copper, aluminium or tungsten.

In the copper CMP processes, excess copper is planed or “polished” off from the top of the wafer surface to expose the thin pattered lines of copper metal inlaid within the barrier layer or substrate material. Copper CMP is performed by rotating a copper plated wafer in pressurized contact with a rotating polishing pad onto which with a liquid chemical oxidant and abrasive material are dispensed. Typical liquid oxidants for the copper CMP process include hydrogen peroxide and ferric chloride, and examples of typical abrasive slurry materials include approximately 0.01 micrometer diameter alumina or silica particles in a concentration of about 1 to 7 weight percent. Polishing of the substrate continues until the underlying substrate is exposed, a condition commonly referred to as breakthrough. For copper CMP, breakthrough is defined as removal of metal from the top of the substrate until the underlying barrier layer or dielectric is first exposed. Breakthrough can be detected by optical reflectance from the substrate, by changes in polishing wheel temperature, by changes in polishing wheel torque, or by changes in chemical composition of used polishing solution. Once the excess copper is removed by the polishing step, the wafer must be cleaned with additional chemicals and soft pads to remove the abrasive particles that adhere to the wafer.

To create advanced semiconductor devices, those that contain multiple levels of metal lines and dielectric, will require the use of new dielectric materials. These new dielectric materials are commonly referred to as low-k dielectrics. Unlike the traditional silicon dioxide dielectric which is relatively hard and has a toughness of about 0.7 Mpa/m^{0.5}, the newer low k dielectrics like silsequioxane and nanoporous silicon dioxide are softer and have a toughness of 0.2 Mpa/m^{0.5} and of 0.1 Mpa/m^{0.5} respectively. The large force exerted onto the wafer during typical CMP polishing may damage these fragile low-k dielectrics.

One problem with the CMP process is the excess removal of substrate material from a wafer. Such excess removal during a CMP polishing step will cause deviations in wafer planarity that could result in wafer defects created in subsequent photolithographic or metalization steps. Polishing of metal surfaces using slurry-based chemical mechanical planarization also results in dishing. Dishing is defined as removal of metal from the interconnect below the top level of the barrier layer. Dishing causes an increase in the electrical resistivity of the copper interconnect because the conductor is thinner than it was designed to be. Increased resistivity can lead to overheating that will cause the semiconductor device to fail.

The excessive removal of metal and barrier materials from the patterned substrate using slurry based chemical mechanical planarization is called erosion. Erosion can lead to a non-planar topography across the wafer that can cause short circuits to form in subsequently deposited metal layers.

Additional problems with CMP include scratching of fine line metal and dielectric features by the agglomerations of abrasive particles. Scratching results in damaged interconnects and yield loss. Agglomerated particles and gels can be removed from the slurries using point of use filtration prior to substrate polishing, however plugging of the filters requires interruption of the process for filter removal which is expensive and results in lower production. Agglomerated slurry particles also plug the surface of the polishing pad and polishing pads must be periodically reconditioned in a non-value added step called dressing.

As part of the chemical mechanical planarization process, cleaning of the wafers is also required to remove the abrasive particles from the polished wafer surfaces. Costly wafer cleaning tools are required to perform this operation. The added cleaning step increases production costs and decreases wafer throughput. Chemicals and large amounts of water are required by the wafer-cleaning tool to remove the particles from the wafers leading to additional costs and added volumes of generated chemical waste.

Several inventions have been disclosed which attempt to eliminate the problems with conventional slurries based CMP processes. For example, U.S. Pat. No. 6,238,592 B1 describes a slurry-less metal polishing process with a working liquid composed of an oxidant, a buffer, an iminodiacetic acid chelating agent, benzotriazole as corrosion inhibitor, and a polishing pad with the abrasive embedded or fixed into the pad. The process is used to polish copper interconnects on semiconductor substrates. Typical pressures between the fixed abrasive pad and substrate used in the disclosed process are from 3 to 4 pounds per square inch or 206.8 to 275.8 grams per square centimeter. Such conditions are used to achieve useful copper removal rates of from 0.17 to 0.42 micrometers per minute of copper from patterned substrates with dishing in 100 micrometer square bond pads ranging from 0.034 to 0.21 micrometers. Although such a process eliminates the need for an suspended abrasive in the polishing liquid, it still requires the use of an abrasive article and high pressure between the pad and substrate to achieve the stated copper removal rates. Such high pressures are not desirable especially for delicate low-k dielectric materials. Fixed-abrasive pads are more expensive to than other types of polishing pads which further adds to the cost of the overall CMP process.

U.S. Pat. No. 6,117,775 discloses a chemical mechanical planarization process for copper. A chemical polishing solution containing an acid, oxidant, benzotriazole inhibitor, and optionally up to 1% weight percent suspended abrasives are used with a rubbing pad to remove copper metal from a surface. The combination of acid and oxidant is such that the solution is in the regime of copper corrosion as typically depicted by the Pourbaix diagram or similar method. The copper removal rate as disclosed in the examples of U.S. Pat. No. 6,117,775 without an added abrasive are low, for example 84 nanometers per minute in the absence of an inhibitor, and lower still in the presence of an inhibitor 14 nanometers per minute. Such a rate would not be useful or commercially viable for semiconductor manufacturing.

Similar polishing processes to U.S. Pat. No. 6,117,775 have been disclosed by S. Kondo et al in the Journal of the Electrochemical Society, volume 147, page 3907, 2000. In this disclosure the removal rate of copper is 100 nanometers per minute at pressures of about 60.2 grams per square centimeter and linear velocity of about 47 centimeters per second on the substrate. Higher copper removal rates, approaching 200 nanometers per minute, were achieved but required higher pressure, 220 grams per square centimeter, of the substrate on the polishing pad. This is not desirable since delicate low-k dielectrics to be used in future VLSI circuits can be damaged by such pressures. Increased pressure between the polishing pad and substrate can also result in excessive dishing as the pad is deformed into the trenches on the wafer.

Other abrasive free copper polishing systems have disclosed by Jason Keleher and co-workers, Mar. 7-8, 2001 CMP-MIC Conference pp 449. In one example a solution containing hydrogen peroxide, an amino acid, and an undisclosed quencher is used to polish copper; in a second example a solution containing ammonium persulfate, an inhibitor benzentriazol, and an unidentified chemical termed an accelerant were used to polish copper. Polishing conditions such as pad type and size, rotational rate, and pad to wafer pressure were not disclosed.

U.S. Pat. No. 6,228,771 discloses a two step chemical mechanical polishing process using an abrasive polishing solution and polishing pad system wherein the first polishing step occurs at high polishing pad to wafer contact pressures, up to 6 pounds per square inch, psig, and the second step at lower pad to wafer pressures of 3 pounds per square inch. The process uses high pad to wafer pressure to effect fast removal of material in the initial stage of the polishing process, usually breakthrough, and then lower pressure in the second stage to reduce the copper removal rate and also to reduce dishing. The polishing removal rate of abrasive containing systems increases linearly with pressure and is called Prestonian behavior. Such behavior is not observed in non-abrasive CMP polishing systems; removal rate increases linearly at very low pressures but saturates to an essentially constant value at higher pressures as disclosed by S. Kondo et al in the Journal of the Electrochemical Society, volume 147, page 3907, 2000. Since the copper removal rate is low at low pressures in non-abrasive polishing systems, such a process as disclosed in U.S. Pat. No. 6,228,771 would not be useful. The use of high pressures, especially 6 psig and even 3 psig would not permit the polishing of substrates containing delicate low-k dielectrics.

U.S. Pat. No. 6,217,416 teaches that for slurry based CMP polishing of copper, a preferred mechanism for polishing is to continuously form a thin abradable layer on the metal by reaction of one or more components of the polishing liquid with the metal. The thin abradable layer is removed by mechanical action of the slurry against the substrate. Once mechanical polishing ceases a thin passive layer remains on the metal surface to reduce wet chemical etching of the metal. Removal rates disclosed in this invention using alumina slurry range from 0.26 to 0.47 micrometers per minute with 182 grams per square centimeter pressure, about 3 psig. Acetic acid is disclosed to reduce copper removal in a polishing example.

In general it is well known in the art that copper chemical etching is achieved by first oxidizing copper metal to copper oxide. The oxidized copper is then removed by exposing to an acid. Selectivity between the peak and valley of the surface may be achieved by the mechanical force exerted between the rotating wafer and the polishing pad to remove the oxide or protective layer. This method requires either large force and/or the presence of abrasives in order to achieve reasonable removal rate, which may result in damage to the wafer, scratches, oxide erosion or copper dishing.

All the inventions and disclosures sited above involve copper oxidation by a corrosive polishing solution and removal by either mechanical abrasion or acid etching. While such polishing solutions lie within the domain of corrosion of the metal, such solutions do not a necessarily provide for high metal removal rates nor do they create a smooth polished metal film surface both qualities are required for semiconductor wafer polishing.

There exists a need in the semiconductor industry to polish thin metal films and fine copper interconnect lines inlaid on a patterned substrate that is comprised of dielectric or barrier layer materials. The metal films and interconnect lines and patterns revealed by polishing should be substantially free from scratches, dishing and erosion. The process to polish fine copper interconnect lines and metal films on a patterned substrate should be yield smooth surfaces, have a high removal rate and operate at low pressure. It is further desirable to be able to control the removal rate of the metal from the substrate without changing pressure or rotational rate of the polishing pad or substrate.

### SUMMARY OF THE INVENTION

The present invention relates to a process for selectively polishing a metal layer on a patterned substrate using a slurry free liquid composition and a polishing pad. The invention is useful in the polishing of semiconductor substrates.

The present invention relates to a polishing process in which the surface of a metal layer is contacted with a liquid composition and then the surface of the metal is planarized with a polishing pad.

In a preferred embodiment, the rate of polishing of the metal substrate is controlled by adjustment of the chemical composition of the liquid used in the polishing solution.

In another preferred embodiment, the polishing solution is prepared by dissolving gaseous forms of the oxidizer and or the acid for the buffer into the liquid so that fresh polishing solutions can be generated.

The present invention provides for slurry free polishing of semiconductor wafer substrates containing thin metal films and inlaid metal interconnects at high rates with little dishing or erosion. The polished films are smooth and do not contain scratches. The process and liquid composition of the present invention is advantageous in that it provides higher metal removal rates at lower pad to wafer pressures compared to the prior art and is compatible with the processing of substrates containing delicate low-k dielectrics. A further advantage of the present invention is that it permits control of the removal rate of metal from the substrate by variation of the liquid polishing composition.

### BRIEF DESCRIPTION OF THE DRAWINGS

FIG. 1 is an interferogram of a patterned substrate, Mode N, following polishing of a plated substrate utilizing the process of this invention with formic acid.

FIG. 2(a) is an interferogram of a patterned substrate, Mode P, following polishing of a plated substrate utilizing the process of this invention with a formic acid containing buffer solution.

FIG. 2(b) is an interferograrn of a patterned substrate, Mode O, following polishing of a plated substrate utilizing the process of this invention with with a formic acid containing buffer solution.

FIG. 3(a) is an interferogram of a patterned substrate, Mode N, following polishing of a plated substrate utilizing the process of this invention with a formic acid containing buffer solution.

FIG. 3(b) is an interferogram of a patterned substrate, Mode L, following polishing of a plated substrate utilizing the process of this invention with with a formic acid containing buffer solution.

FIG. 4(a) is an interferogram of a patterned substrate, Mode N, following polishing of a plated substrate utilizing the process of this invention with a formic acid containing buffer solution at reduced substrate to polishing pad pressure.

FIG. 4(b) is an interferogram of a patterned substrate, Mode L, following polishing of a plated substrate utilizing the process of this invention with with a formic acid containing buffer solution at reduced substrate to polishing pad pressure.

FIG. 5(a) is an interferogram of a patterned substrate, Mode P, following polishing of a plated substrate utilizing the process of this invention with a formic acid containing buffer solution with 200 parts per million by weight of the inhibitor benzotriazole.

FIG. 5(b) is an interferogram of a patterned substrate, Mode L, following polishing of a plated substrate utilizing the process of this invention with a formic acid containing buffer solution with 200 parts per million by weight of the inhibitor benzotriazole.

FIG. 5(c) is an interferogram of a patterned substrate, Mode H, following polishing of a plated substrate utilizing the process of this invention with a formic acid containing buffer solution solution with 625 parts per million by weight of the inhibitor.

FIG. 6(a) is an interferogram of a patterned substrate, Mode N, following polishing of a plated substrate utilizing the process of this invention with a phosphoric acid containing buffer solution.

FIG. 6(b) is an interferogram of a patterned substrate, Mode L, following polishing of a plated substrate utilizing the process of this invention with a phosphoric acid containing buffer solution.

FIG. 7(a) is an interferogram of a patterned substrate, Mode N, following polishing of a plated substrate utilizing the process of this invention with an acetic acid containing buffer solution.

FIG. 7(b) is an interferogram of a patterned substrate, Mode L, following polishing of a plated substrate utilizing the process of this invention with an acetic acid containing buffer solution.

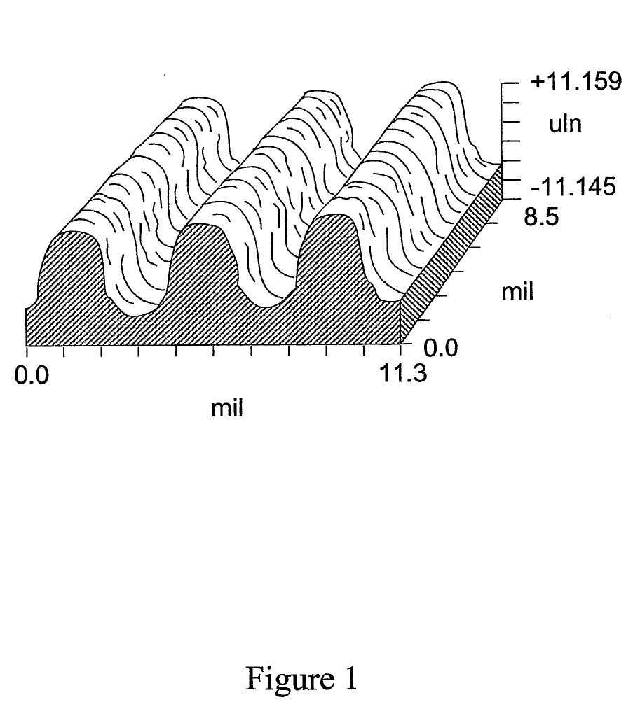

### DETAILED DESCRIPTION OF THE INVENTION

This invention will be described in the following by reference to numerous specific details, materials, structures, chemicals and processes. In this detailed description, reference will be made to various figures where certain features are identified by reference numerals. Furthermore, although the preferred embodiment is described in reference to the copper polishing process, it is appreciated that the liquid composition and polishing process described herein is for exemplary purposes only and that techniques of the present invention can be readily adapted to other metals and alloys.

The present invention provides a process and liquid composition for polishing a metal film. The metal may be a continuous film and includes a metal inlaid in a patterned barrier layer of vias and trenches on a substrate. In a preferred embodiment of this invention the metal film contains copper or one of its alloys. Patterned tantalum and tantalum nitride barrier layer substrates with plated with copper are available from Sematech International, Austin, Tex. Examples of other suitable barrier layer materials used in copper interconnect structures include but are not limited to Mo, TiW, TiN, WN, TiSiN, TaSiN and CoWP.

The patterned substrate containing the copper layer deposited on the barrier layer is treated by first exposing the entire wafer substrate to a liquid composition polishing solution. Liquid compositions used as polishing solutions and useful in the practice of the current invention contain an oxidant, a buffer, and an inhibitor all dissolved in water.

A preferred oxidizer useful in the practice of this invention include hydrogen peroxide at a concentration of 0.5 to 10 percent and more preferably 1 to 6 percent by volume. Other oxidizers useful in the practice of this invention include ferric chloride, ammonium persulfate, and ozone are also useful either alone or in combination.

A preferred buffer useful in the practice of this invention is formic acid and ammonium formate. More preferably a formic acid and sodium formate buffer or an acetic acid and sodium acetate buffer are used. Other useful buffer systems for the practice of this invention include phosphoric acid and potassium hydrogen phosphate, carbonic acid and ammonium bicarbonate, citric acid and ammonium citrate, tartaric acid and ammonium tartarate. In general any organic acid and its conjugate weak base as an alkali, alkaline earth, or ammonium salt can be used in the practice of this invention. In general any inorganic acid and its conjugate weak base as an alkali, alkaline earth, or ammonium salt can also be used in the practice of this invention. An organosulfonic acid, like 2-acrylamido-2-methyl 1-propanesulfonic acid or benzenesulfonic acid, and buffer also containing acetic acid and ammonium acetate is also useful in the practice of this invention.

In the practice of this invention it has been found advantageous to improve the removal rate of metal from the substrate to add an alkali, alkaline earth, or ammonium salt of a sulfate or formate anion to the buffer. Examples of such salts include ammonium sulfate and ammonium formate.

It is preferred that the pH of the buffer in the liquid composition should be within ±2 pH unit of the pKₐ of the acid. The concentration of salt of the conjugate base in the buffer is preferred to be in the range of 0.00025 to 0.1 moles per liter.

A preferred inhibitor useful in the practice of this invention is benzotriazole at a concentration of from 10 to 10,000 parts per million, and more preferably from 100 to 1000 parts per million by weight. Other useful inhibitors in the practice of this invention include derivatives of benzotriazole, imidazole, analine, and tolytriazole. Surfactants, for example Triton X, available from Union Carbide Corporation, Danbury, Conn., are also useful in the practice of this invention and can be added to the inhibitor solution.

In a preferred embodiment of this invention, the patterned substrate contacted with the liquid composition is rubbed with a polishing pad. In the present invention, an example of a useful polishing pad material for removing copper from a patterned substrate is a polyurethane polishing pad from Rodel, Newark, Del. Other suitable polishing pads for removing copper from substrates in the present invention include fixed abrasive or three dimensional abrasive articles as described in U.S. Pat. Nos. 5,692,950 and 6,238,592 B1 which are incorporated by reference in their entirety. Other suitable polishing pad materials include ultrahigh moleuclar weight polyethylene, or a cation exchange membrane, for example CR67-HMR-412 from Ionics, Watertown, Mass.

The linear velocity at which the wafer and polishing pad are rotated with respect to each other range from 0 to 500 cm/sec, more preferably from 20 to 100 cm/sec. Polishing can be performed by rotational, orbital, or linear motion of the polishing pad and wafer. Examples of such polishers include the Mirra Mesa orbital polisher from Applied Materials, San Jose, Calif., a SpeedFam-IPEC (SFI) Momentum orbital polisher, SpeedFam-IPEC Incorporated, Chandler, Ariz.

The pressure at which the wafer and polishing pad are contacted can range from 10 to 300 grams per square centimeter, 1 to 30 kilopascals, with a preferred pressure of from 10 to 60 grams per square centimeter, 1 to 30 kilopascals, or less. The pressure between the polishing pad and wafer is commonly refered to as the downward force.

The rate at which the liquid composition polishing solution is applied to the polishing pad should be sufficient to provide lubrication and reaction with the metal on the wafer. Dispense rates of liquid composition used in the practice of this invention range from 5 milliliters to 500 milliliters per minute, and more preferably from 10 milliliters per minute to 200 milliliters per minute.

Polishing of the substrate continues until the metal is removed from the substrate.

Endpoint detection of the metal removal polishing process can be made by measurement of temperature, motor current or by optical methods as described in “Full Wafer Endpoint Detection Improves Process Control in Copper CMP;” B. W. Adams et al.; Semiconductor Fabtech, 12^{th} edition, pp 283; and references therein.

After polishing, the patterned substrate containing the metal inlaid within the barrier layer in the vias and trenches is treated by immersion or contact with an acid containing solution to remove excess inhibitor from the polishing step. Useful acids for cleaning the substrate include hydrochloric and methane sulfonic acid. A preferred acid is 10 percent by volume sulfuric acid at a pH of 0. The acid-cleaned substrate is washed with deionized water until water rinse from the coupon has a resistivity of between 10 and 18.2 mega ohms.

The following example illustrates the present invention and is not intended to limit the same.

### EXAMPLES OF THE PRESENT INVENTION

The following procedures were employed in the testing of the referred herein.

Procedure 1

Patterned copper coupons from Sematech International, Austin, Tex., with 1.5 micrometer thick copper, 0.8 micrometer trenches, and pattern floor plan 926AZ-710 were used for copper polishing experiments. Square samples of the coupons, 2 centimeters on edge, were polished using a Buehler polishing wheel with down pressure of 60.8 or 182.4 grams per square centimeter provided to the back of the patterned coupon. Rotation of the polishing pad on the polishing wheel was 50 or 130 rotations per minute. The copper coupon to be polished was manually positioned on the rotating polishing pad and hand rotated at a rate of approximately 5 to 10 rotations per minute. The copper coupon was checked visually for copper removal at two-minute intervals. The abrasive free polishing pad was 7.62 centimeters in diameter with the distance from the center of the coupon to the center of the polishing pad of about 2.5 centimeters. At a rotation of 130 rotations per minute the linear velocity of the pad below the wafer was about 34 centimeters per second. The abrasive free pad was composed of a surface modified microporous membrane of ultra high molecular weight polyethylene (Procedure 2), or a polyurethane polishing pad from Rodel, Newark, Del. Chemistry for polishing was dispensed to the polishing pad at a rate of about 10 milliliters per minute.

Procedure 2 (Polishing Pad Base Membrane Preparation)

A mixture consisting of UPE powder (240S, Mitsui), C-IEX (Microlite PrCH, Purolite) resin and mineral oil (Britol 35 USP, Witco) at a composition ratio of 1:7:9 by weight was prepared at room temperature. This mixture has a consistency of viscous slurry. It was mechanically homogenized and metered via a FMI pump (Fluid Metering Inc., model QV) into a twin-screw compounder (Brabender 05-96-000) equipped with a pair of 42 mm slotted counter-rotating screws (LID=6). Melting and dissolution of UPE and dispersing of C-IEX particles occurred inside the compounder. A Zenith gear pump (Parker Hannifin 60-20000-0847-4), a static mixer (Koch Engineering, 2.5 cm. diameter×150 cm. length) and a flat sheet die with a slot opening of 17.8 cm in width were also attached downstream to the compounder for extrusion of the melt blend into sheet form. The temperatures of the various zones of the extrusion line were set at between 170° and 180° C.

The extruded sheet was quenched on a rotating chill roll whose temperature was controlled by recirculating constant temperature fluid at 70° C. Quenched gel sheet was rolled up by a motorized winder interleaved with a layer of polypropylene non-woven. To extract the mineral oil from the quenched sheet, the membrane roll was placed in a Baron-Blakslee degreaser containing 1,1-dichloro-1-fluoroethane for reflux extraction for 16 hrs. After extraction the porous membrane containing ultra high molecular weight polyethylene and cation ion exchange resin was dried at room temperature. Its thickness is ˜1 millimeter.

Surface Treatment

A strip of the base membrane was cut, pre-wet with isopropyl alcohol and immersed in DI water for conditioning before treatment. A monomer treatment solution consisting of 2-acrylamido-2-methyl-1-propanesulfonic acid (Aldrich), N,N′-methylenebisacrylamide (Aldrich), 2-hydroxy-4′hydroxyethoxy-2-methylpropiophenone (Irgacure 2959, Ciba) and DI water at a composition of 5.4:1.3:0.3:97.0 weight ratio was prepared. The conditioned membrane was then soaked in this treatment solution for approximately ˜30 mins. The soaked membrane was sandwiched between 2 thin polyethylene films and lightly squeegeed to remove excess solution inside the sandwich. The sandwiched membrane was then exposed to ultra-violet radiation for initiation of reactions between the monomers on the membrane surface by passing it through an ultraviolet light Curing System (I300B with “H” bulb, Fusion Curing Systems) at a speed of 10 feet per minute. Afterwards, the treated membrane was removed from the sandwich and washed with DI water. This water-wet membrane was placed in a sodium sulfate saturated aqueous solution for 2 hours, rinsed with water and used as a rubbing pad for polishing.

### EXAMPLE 1

In this example the polishing rate of a patterned copper substrate using the process of this invention with a liquid composition in the zone of corrosion of the metal is detailed. The liquid composition in this example does not contain the weak conjugate base salt of the acid used in the liquid composition.

A patterned copper coupon from Sematech with patterned floor plan 926AZ-710 and 1.5 micrometer thick copper and tantalum nitride barrier layer was planarized using about 182.4 grams per square centimeter down force on a 7.62 centimeter diameter polyurethane IC1000 rubbing pad, obtained from Rodel, Newark, Del. The rubbing pad was rotated at 130 rotations per minute, the linear velocity was about 34 centimeters per second. The 1 liter aqueous chemical polishing solution contained 5% by volume hydrogen peroxide, 200 parts per million by weight benzotriazole, 0.019 milliliters formic acid, Aldrich Chemical, Milwaukee, Wis., added to bring the solution to a pH of 3.2.

The polishing solution was dispensed onto the rubbing pad at a rate of about 10 milliliters per minute. Polishing was stopped after 10 minutes with portions of the substrate planarized to a flattened copper surface-0.85 micrometers of copper removed. Removal rate was determined to be about 0.085 micrometers per minute.

### EXAMPLE 2

In this example the polishing rate of a copper coupon using the process and liquid composition of example 1 but with weak acid conjugate base added to the solution, as disclosed in the liquid composition of the present invention, is detailed.

A patterned copper coupon from Sematech with patterned floor plan 926AZ-710 and 1.5 micrometer thick copper and tantalum nitride barrier layer was planarized using about 182 grams per square centimeter down force on a 7.62 centimeter diameter polyurethane IC1000 rubbing pad, obtained from Rodel, Newark, Del. The rubbing pad was rotated at 130 rotations per minute and the linear velocity was about 34 centimeters per second. The 1 liter aqueous chemical polishing solution contained 5% hydrogen peroxide by volume, 200 parts per million by weight benzotriazole (0.001679 mole), and a buffer containing 0.63 grams ammonium formate with 1.1 milliliters formic acid, Aldrich Chemical, Milwaukee, Wis., added to bring the solution to a pH of 3.2.

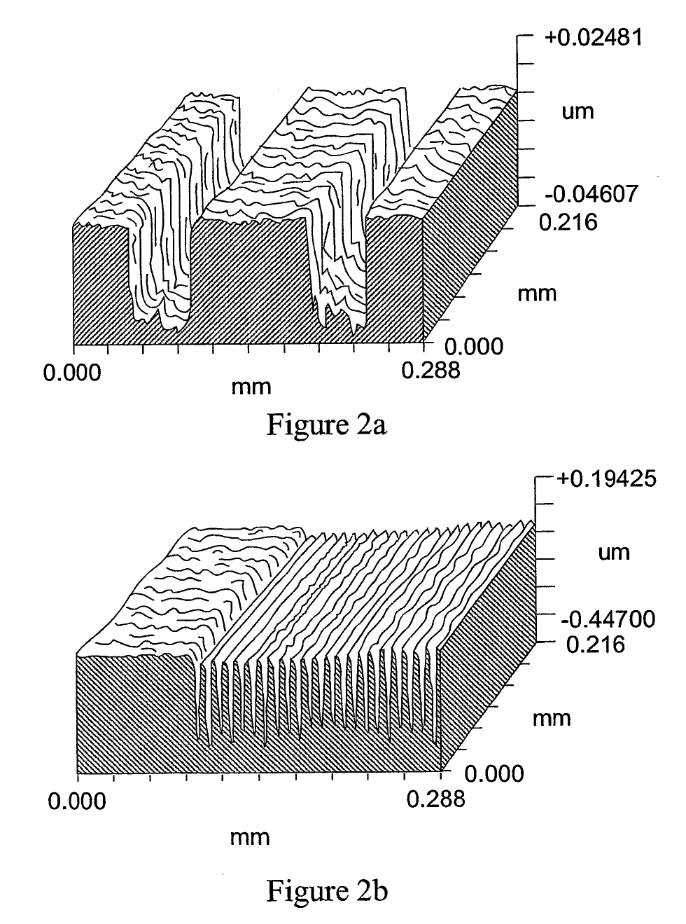

The polishing solution was dispensed onto the rubbing pad at a rate of about 10 milliliters per minute. Polishing was stopped when all copper was removed from the portions of the barrier layer surface that did not include trenches. Removal rate was determined to be 0.27 micrometers per minute. Interferometric analysis of the polished coupon was made using a Zygo Interferometer (Middlefield, Conn.) with a 50× objective lens. The patterns after polishing and labeled Mode P (50 micrometer line width, 150 micrometer pitch) and Mode 0 (1.5 micrometer line width, 4.5 micrometer pitch) on the 926AZ-710 floor plan are shown in FIG. 2a and FIG. 2b respectively. The depth of the trench in the absence of copper is about 0.87 micrometers. Interferometric analysis of line Mode P in FIG. 2a. shows a polished trench depth of 0.05 micrometers which means that 0.82 micrometers of copper remains in the trench. Interferometric analysis of line Mode O in FIG. 2(b) shows a polished trench depth of 0.09 micrometers which means that 0.78 micrometers of copper remains in the trench.

### EXAMPLE 3

In this example the polishing rate of a copper coupon using the process of this invention but with alkali metal conjugate base salt substituted for the ammonium conjugate base salt used in the liquid composition of example 2.

A patterned copper coupon from Sematech with patterned floor plan 926AZ-710 and 1.5 micrometer thick copper and tantalum nitride barrier layer was planarized using about 182 grams per square centimeter down force on a 7.62 centimeter diameter polyurethane IC1000 rubbing pad, obtained from Rodel, Newark, Del. The rubbing pad was rotated at 130 rotations per minute. The 1 liter aqueous chemical polishing solution contained 5% hydrogen peroxide by volume, 200 parts per million by weight benzotriazole (0.001679 mole), and a buffer containing 0.6802g sodium formate with 1.1 milliliters formic acid, Aldrich Chemical, Milwaukee, Wis., added to bring the solution to a pH of 3.2.

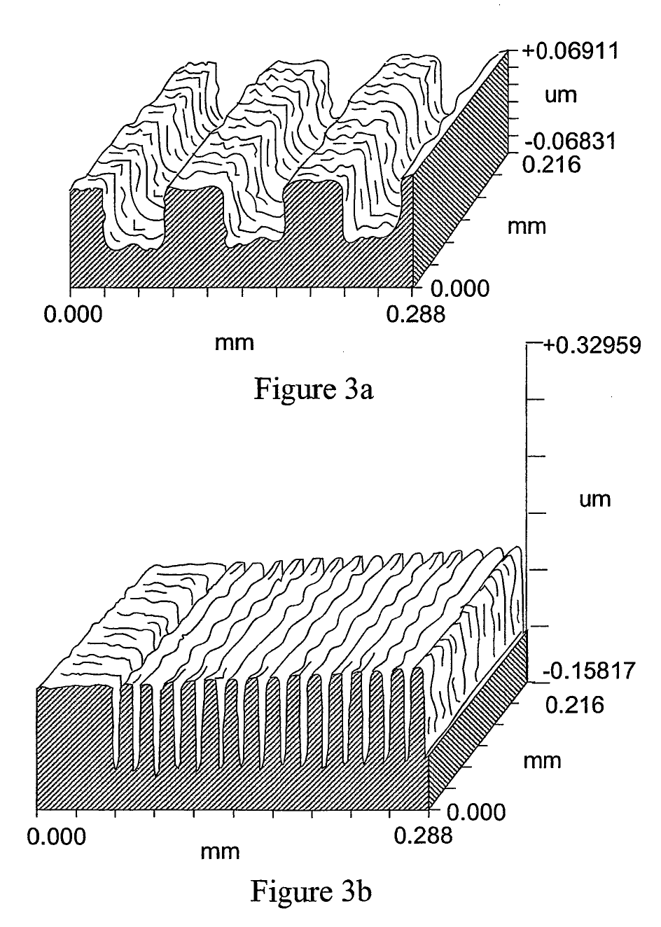

The polishing solution was dispensed onto the rubbing pad at a rate of about 10 milliliters per minute. Polishing was stopped when all copper was removed from the portions of the barrier layer surface that did not include trenches. Removal rate was determined to be 0.38 micrometers per minute. Interferometric analysis of the polished coupon was made using a Zygo Interferometer (Middlefield, Conn.) with a 50× objective lens. The patterns after polishing and labeled Mode N (50 micrometer line width, 100 micrometer pitch) and Mode L (10 micrometer line width, 20 micrometer pitch) on the 926AZ-710 floor plan are shown in FIG. 3a and FIG. 3b respectively. The depth of the trench in the absence of copper is about 0.87 micrometers. Interferometric analysis of line Mode N in FIG. 3a. shows a polished trench depth of 0.098 micrometers which means that 0.77 micrometers of copper remains in the trench. Interferometric analysis of line Mode L in FIG. 3(b) shows a polished trench depth of 0.15 micrometers which means that 0.72 micrometers of copper remain in the trench.

### EXAMPLE 4

In this example the polishing rate of a copper coupon with the process and liquid composition from example 3, but at reduced polishing pad to coupon pressure of 60.8 grams per square centimeter is disclosed.

A patterned copper coupon from Sematech with patterned floor plan 926AZ-710 and 1.5 micrometer thick copper and tantalum nitride barrier layer was planarized using about 60.8 grams per square centimeter down force on a 7.62 centimeter diameter polyurethane IC1000 rubbing pad, obtained from Rodel, Newark, Del. The rubbing pad was rotated at 130 rotations per minute. The 1 liter aqueous chemical polishing solution contained 5% hydrogen peroxide by volume, 200 parts per million by weight benzotriazole (0.001679 mole), and a buffer containing 0.6802 g sodium formate with 1.1 milliliters formic acid, Aldrich Chemical, Milwaukee, Wis., added to bring the solution to a pH of 3.2.

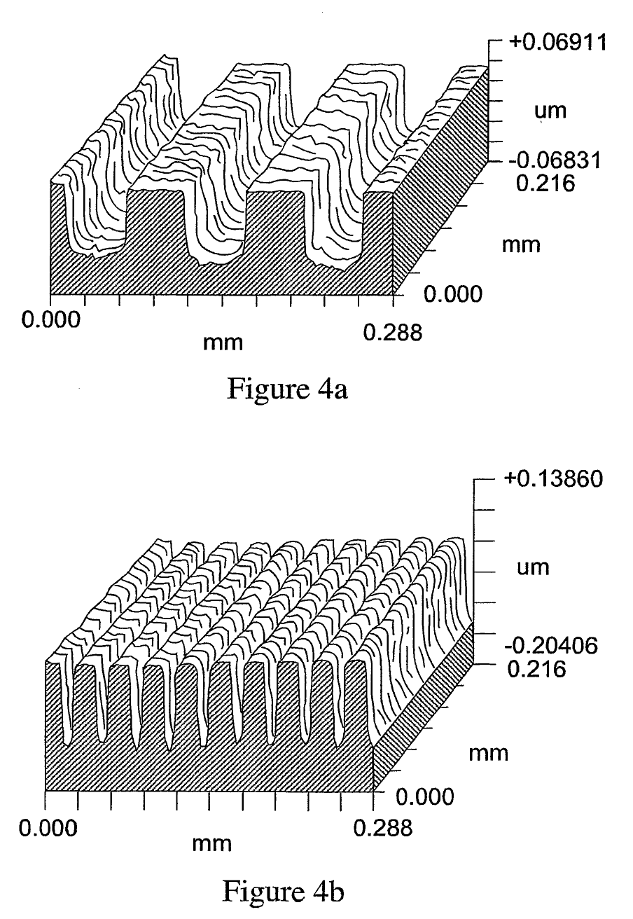

The polishing solution was dispensed onto the rubbing pad at a rate of about 10 milliliters per minute. Polishing was stopped when all copper was removed from the portions of the barrier layer surface that did not include trenches. Removal rate was determined to be 0.19 micrometers per minute. Interferometric analysis of the polished coupon was made using a Zygo Interferometer (Middlefield, Conn.) with a 50× objective lens. The patterns after polishing and labeled Mode N (50 micrometer line width, 100 micrometer pitch) and Mode L (10 micrometer line width, 20 micrometer pitch) on the 926AZ-710 floor plan are shown in FIG. 4a and FIG. 4b respectively. The depth of the trench in the absence of copper is about 0.87 micrometers. Interferometric analysis of line Mode N in FIG. 4a. shows a polished trench depth of 0.21 micrometers which means that 0.66 micrometers of copper remains in the trench. Interferometric analysis of line Mode L in FIG. 4(b) shows a polished trench depth of 0.13 micrometers which means that 0.74 micrometers of copper remain in the trench.

### EXAMPLE 5

In this example the polishing rate of copper coupons using the process and liquid composition described in this invention is controlled by using different inhibitor concentrations in the liquid composition.

A copper coupon from Sematech with patterned floor plan 926AZ-710 and 1.5 micrometer thick copper and tantalum nitride barrier layer was planarized using about 182 grams per square centimeter down force on a 7.62 centimeter diameter polyurethane IC1000 rubbing pad, obtained from Rodel, Newark, Del. The rubbing pad was rotated at 130 rotations per minute. The 1 liter aqueous chemical polishing solution contained 5% hydrogen peroxide by volume, 200 parts per million by weight benzotriazole (0.001679 mole), and a buffer containing 2.52 g ammonium formate with about 3.2 milliliters formic acid, Aldrich Chemical, Milwaukee, Wis., added to bring the solution to a pH of 3.2.

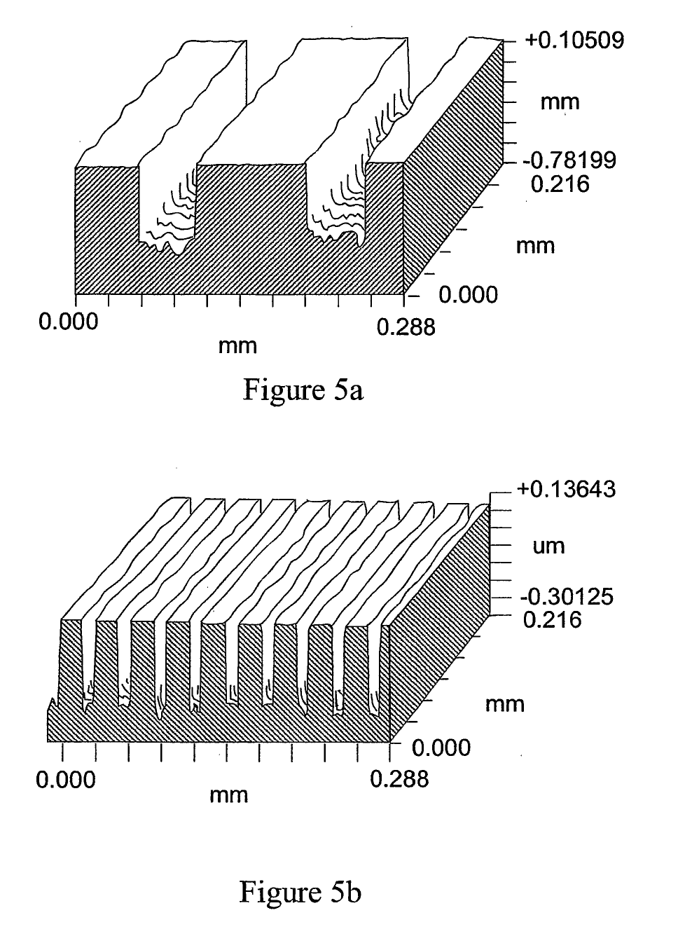

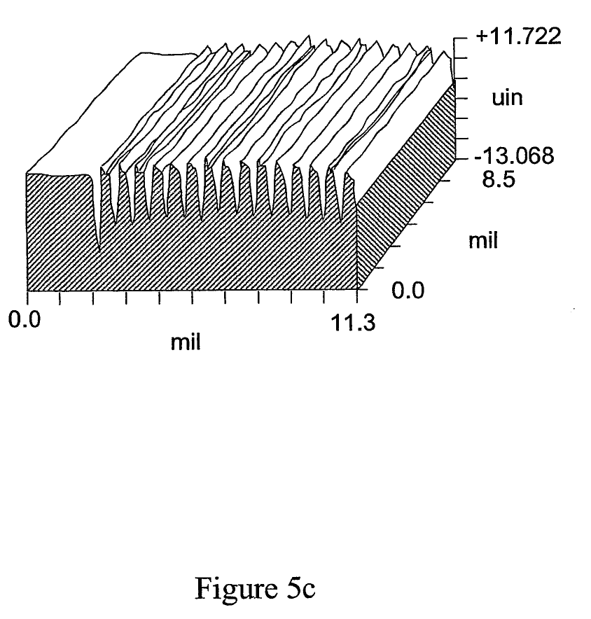

The polishing solution was dispensed onto the rubbing pad at a rate of about 10 milliliters per minute. Polishing was stopped when all copper was removed from the portions of the barrier layer surface that did not include trenches. Removal rate was determined to be 0.3 micrometers per minute. Interferometric analysis of the polished coupon was made using a Zygo Interferometer (Middlefield, Conn.) with a 50× objective lens. The patterns after polishing and labeled Mode P (50 micrometer line width, 150 micrometer pitch) and Mode L (10 micrometer line width, 20 micrometer pitch) on the 926AZ-710 floor plan are shown in FIG. 5(a) and FIG. 5(b) respectively. The depth of the trench in the absence of copper is about 0.87 micrometers. Interferometric analysis of line Mode P in FIG. 5(a). shows a polished trench depth of 0.24 micrometers which means that 0.63 micrometers of copper remains in the trench. Interferometric analysis of line Mode L in FIG. 5(b) shows a polished trench depth of 0.33 micrometers which means that 0.54 micrometers of copper remain in the trench.

A patterned copper coupon from Sematech with patterned floor plan 926AZ-710 and 1.5 micrometer thick copper and tantalum nitride barrier layer was planarized using about 182 grams per square centimeter down force on a 7.62 centimeter diameter polyurethane IC1000 rubbing pad, obtained from Rodel, Newark, Del. The rubbing pad was rotated at 130 rotations per minute. The 1 liter aqueous chemical polishing solution contained 5% hydrogen peroxide by volume, 625 parts per million by weight benzotriazole (0.0052 mole), and a buffer containing 2.72 g sodium formate with about 3.2 milliliters formic acid, Aldrich Chemical, Milwaukee, Wis., added to bring the solution to a pH of 3.2.

The polishing solution was dispensed onto the rubbing pad at a rate of about 10 milliliters per minute. Polishing was stopped after 16 minutes. The removal rate was determined to be 0.12 micrometers per minute at first breakthrough. Interferometric analysis of the polished coupon was made using a Zygo Interferometer (Middlefield, Conn.) with a 50× objective lens. The pattern after polishing labeled Mode H (5 micrometer line width, 15 micrometer pitch) on the 926AZ-710 floor plan is shown in FIG. 5c. The depth of the trench in the absence of copper is about 0.87 micrometers. Interferometric analysis of line Mode H in FIG. 5c. shows a polished trench depth of 0.12 micrometers which means that 0.75 micrometers of copper remains in the trench.

### EXAMPLE 6

In this example the polishing rate of copper coupons using the process and liquid composition of this invention with added acid salt of phosphoric acid is disclosed.

A patterned copper coupon from Sematech with patterned floor plan 926AZ-710 and 1.5 micrometer thick copper and tantalum nitride barrier layer was planarized using about 182 grams per square centimeter down force on a 7.62 centimeter diameter polyurethane IC1000 rubbing pad, obtained from Rodel, Newark, Del. The rubbing pad was rotated at 130 rotations per minute. The 1 liter aqueous chemical polishing solution contained 5% hydrogen peroxide by volume, 200 parts per million by weight benzotriazole (0.001679 mole), and a buffer containing 0.68 grams (0.005 moles) potassium dihydrogenphosphate with 0.4 milliliters phosphoric acid, added to bring the solution to a pH of 2.55.

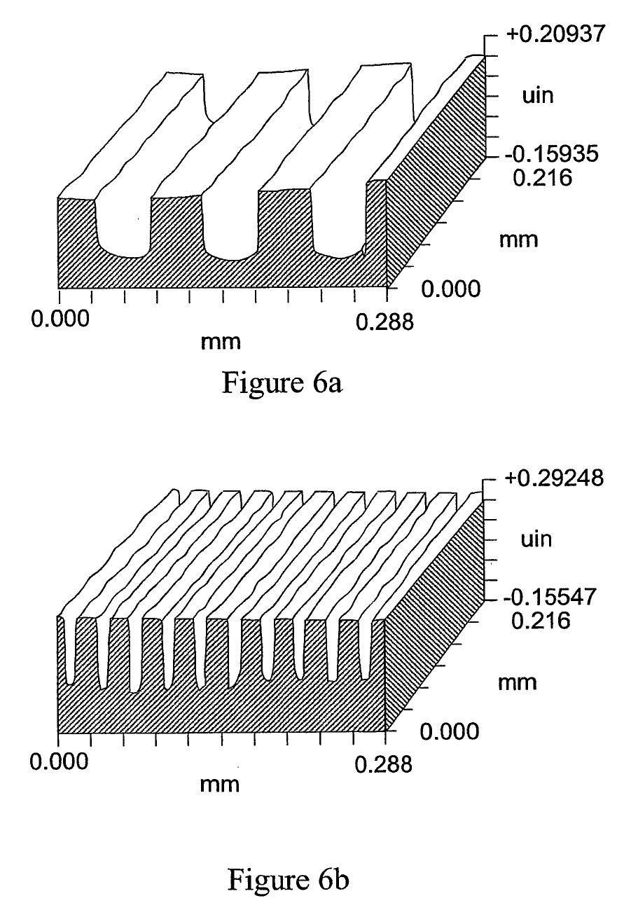

The polishing solution was dispensed onto the rubbing pad at a rate of about 10 milliliters per minute. Polishing was stopped when all copper was removed from the portions of the barrier layer surface that did not include trenches. Removal rate was determined to be 0.25 micrometers per minute. Interferometric analysis of the polished coupon was made using a Zygo Interferometer (Middlefield, Conn.) with a 50× objective lens. The patterns after polishing and labeled Mode N (50 micrometer line width, 100 micrometer pitch) and Mode L (10 micrometer line width, 20 micrometer pitch) on the 926AZ-710 floor plan are shown in FIG. 6(a) and FIG. 6(b) respectively. The depth of the trench in the absence of copper is about 0.87 micrometers. Interferometric analysis of line Mode N in FIG. 6(a) shows a polished trench depth of 0.21 micrometers which means that 0.66 micrometers of copper remains in the trench. Interferometric analysis of line Mode L in FIG. 6(b) shows a polished trench depth of 0.17 micrometers which means that 0.70 micrometers of copper remain in the trench.

### EXAMPLE 7

In this example the polishing rate of a copper coupon using the process and liquid composition of this invention with added acid salt of acetic acid is disclosed.

A patterned copper coupon from Sematech with patterned floor plan 926AZ-710 and 1.5 micrometer thick copper and tantalum nitride barrier layer was planarized using about 182 grams per square centimeter down force on a 7.62 centimeter diameter polyurethane IC1000 rubbing pad, obtained from Rodel, Newark, Del. The rubbing pad was rotated at 130 rotations per minute. The 1 liter aqueous chemical polishing solution contained 4% hydrogen peroxide by volume, 200 parts per million by weight benzotriazole (0.001679 mole), 200 parts per million by weight sodium sulfate, and a buffer containing 0.008 moles sodium acetate with 12 milliliters acetic acid added to bring the solution to a pH of 3.2.

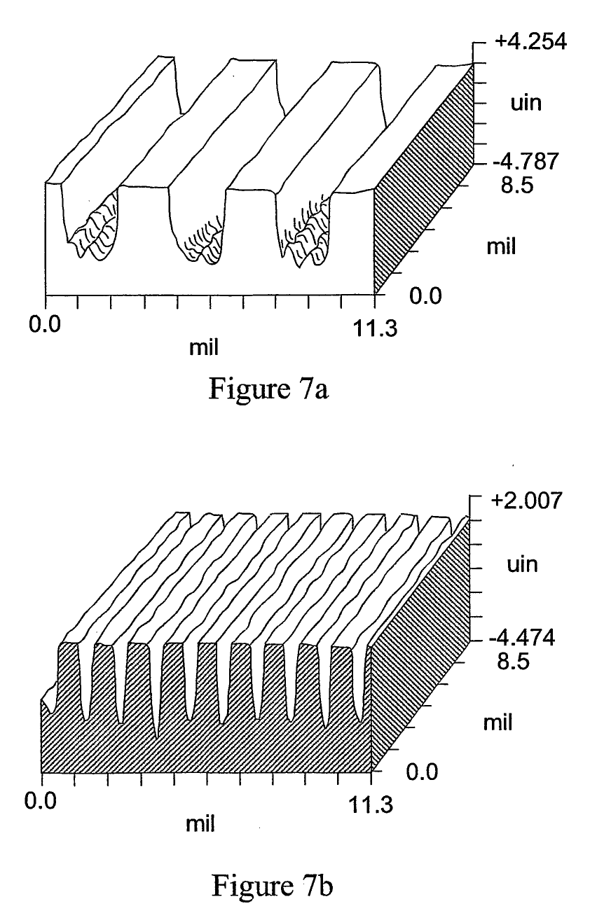

The polishing solution was dispensed onto the rubbing pad at a rate of about 10 milliliters per minute. Polishing was stopped when all copper was removed from the portions of the barrier layer surface that did not include trenches. Removal rate was determined to be 0.19 micrometers per minute. Interferometric analysis of the polished coupon was made using a Zygo Interferometer (Middlefield, Conn.) with a 50× objective lens. The patterns after polishing and labeled Mode N (50 micrometer line width, 100 micrometer pitch) and Mode L (10 micrometer line width, 20 micrometer pitch) on the 926AZ-710 floor plan are shown in FIG. 7(a) and FIG. 7(b) respectively. The depth of the trench in the absence of copper is about 0.87 micrometers. Interferometric analysis of line Mode N in FIG. 7(a). shows a polished trench depth of 0.15 micrometers which means that 0.72 micrometers of copper remains in the trench. Interferometric analysis of line Mode L in FIG. 7(b) shows a polished trench depth of 0.12 micrometers which means that 0.75 micrometers of copper remain in the trench.

### EXAMPLE 8

In this example the polishing rate using the process and liquid composition of this invention shows the comparison of the polishing rate with added acid salt of formic acid with a polyethylene polishing pad prepared by the method of procedure 2.

A patterned copper coupon from Sematech with patterned floor plan 926AZ-710 and 1.5 micrometer thick copper and tantalum nitride barrier layer was planarized using about 182 grams per square centimeter down force on a 7.62 centimeter diameter polyethylene rubbing pad prepared by the method of procedure 2. The rubbing pad was rotated at 130 rotations per minute. The 1 liter aqueous chemical polishing solution contained 5% hydrogen peroxide by volume, 200 parts per million by weight benzotriazole (0.001679 mole), and a buffer containing 0.6802 g sodium formate with 1.1 milliliters formic acid, Aldrich Chemical, Milwaukee, Wis., added to bring the solution to a pH of 3.2.

The polishing solution was dispensed onto the rubbing pad at a rate of about 10 milliliters per minute. Polishing was stopped when all copper was removed from the portions of the barrier layer surface that did not include trenches. Removal rate was determined to be 0.27 micrometers per minute.

1. A process for selectively removing a metal film, the process comprising:
a) contacting the metal film with a buffered liquid composition;
b) contacting the metal film with an abrasive free polishing pad;
c) moving the polishing pad over the film.

2. The process of claim 1, wherein the liquid composition includes an oxidizer.

3. The process of claim 1, wherein the patterned substrate comprises copper or one of its alloys.

4. The process of claim 1 further comprising:
a) detecting the breakthrough of metal removal to the underlying substrate;
b) contacting the metal film on the patterned substrate with a second buffered liquid composition;
c) contacting the metal film with a polishing pad;
d) moving the polishing pad over the substrate;
e) detecting the endpoint of the polishing process.

5. The process of claim 4 wherein the first and second liquid compositions include an oxidizer.

6. The process of claim 4, wherein the first and second liquid compositions differ in their inhibitor concentration.

7. The process of claim 4, wherein the first and second liquid compositions differ in their hydrogen ion concentration.

8. The process of claim 4, wherein the first and second liquid compositions differ in their oxidizer concentration.

9. The process of claim 4, wherein the first and second liquid compositions differ in their conjugate base concentration.

10. The process of claim 4, wherein the first and second liquid compositions differ in their sulfate or formate ion concentration.

11. The process of claim 1 wherein an orbital polisher moves the polishing pad over the substrate.

12. The process of claim 1 wherein a rotational polisher moves the polishing pad over the substrate.

13. The process of claim 1 wherein a belt polisher moves the polishing pad over the substrate.

14. A system for selectively removing the surface of a metal, the system comprising:
A liquid composition including an oxidizer;
a buffer;
an inhibitor, and
a substantially abrasive free pad.

15. The liquid composition of claim 14, wherein the oxidizer is hydrogen peroxide, ferric chloride, ammonium persulfate, or combinations thereof.

16. The liquid composition of claim 14, wherein the buffer comprises an acid and the salt of its conjugate base.

17. The liquid composition of claim 14, wherein the buffer comprises formic acid and formate ion.

18. The liquid composition of claim 14, wherein the buffer comprises citric acid and citrate ion.

19. The liquid composition of claim 14, wherein the buffer comprises phosphoric acid and phosphate ion.

20. The liquid composition of claim 14, wherein the buffer comprises acetic acid and acetate ion.

21. A liquid composition of claim 14, wherein the buffer comprises an organic sulfonic acid and the salt of its conjugate base.

22. A liquid composition of claim 14, wherein the buffer comprises an acid, a salt of its conjugate base, and an added sulfate or formate salt.

23. The liquid composition of claim 14, wherein the inhibitor is benzotriazole, tolytriazole, or imidazole.

24. The liquid composition of claim 14, wherein the inhibitor contains a surfactant.

25. A liquid composition of claim 14, wherein the oxidizer is a gas dissolved in the liquid.

26. A liquid composition of claim 14, wherein the acid for the buffer comprises an acid gas dissolved in the liquid.

27. A liquid composition of claim 25 wherein the gas is ozone.

28. A liquid composition of claim 26 wherein the gas is carbon dioxide.

29. A method for selectively removing a metal film, the method comprising contacting the metal film with a buffered liquid composition; and mechanically removing the metal film, wherein the buffered liquid composition removes metal from the surface at a rate of greater than 0.19 micrometers per minute when subject to a downward polishing force of 1 pound per square inch with a non-abrasive pad moving with a linear velocity of 34 centimeters per second.

30. A liquid composition for removing metal films, the composition comprising a buffer and an oxidizer, the liquid composition characterized by removing metal from the surface at a rate of greater than 0.19 micrometers per minute subject to a downward polishing force of 1 pound per square inch with a non-abrasive pad moving with a linear velocity of 34 centimeters per second.
